(19) United States
(12) Patent Application Publication
(10) Pub. No.: US 2012/0005126 A1
(43) Pub. Date: Jan. 5, 2012

(54) CHARGING/DISCHARGING APPARATUS AND CHARGING/DISCHARGING METHOD

(75) Inventors: Jung Hwan OH, Seoul (KR); Jae Seong Park, Daejeon (KR); Dong Min Son, Suwon (KR)

(73) Assignee: LSIS CO., LTD.

(21) Appl. No.: 13/165,699

(22) Filed: Jun. 21, 2011

(30) Foreign Application Priority Data
Jul. 2, 2010 (KR) 10-2010-0064089

(51) Int. Cl. G01R 11/57

(52) U.S. Cl. 705/412

(57) ABSTRACT

Disclosed is a charging/discharging apparatus and charging/discharging method. According to the present disclosure, a user can suitably control a battery charging/discharging under a price changing system in which electricity price varies depending on time of day. To do this, after the user input a charging reference price and a discharging reference price, the battery is charged when electricity price supplied from a power company is equal to or less than the charging reference price and discharged when the electricity price is equal to or higher than the discharging reference price. A charging/discharging schedule of the battery can be determined using various charging/discharging conditions, other than the charging reference price and discharging reference price, and especially the charging/discharging schedule can be controlled such that the user can make the most profit.

Pursuant to 35 U.S.C. §119 (a), this application claims the benefit of earlier filing date and right of priority to Korean Patent Application No. 10-2010-0064089, filed on Jul. 2, 2010, the contents of which are hereby incorporated by reference in their entirety.

### BACKGROUND OF THE DISCLOSURE

1. Field of the Invention

The present disclosure relates to a charging/discharging apparatus and a charging/discharging method. More particularly, the present disclosure enables users to use electric energy more actively by suitably controlling a battery charging and discharging according to electricity price in a smart grid society in which changes in electricity price according to time of day, so as to use electric energy more economically or resell it as a product.

2. Description of the Related Art

Until now, electric energy has been provided depending on demand, and electricity price also has been fixedly maintained.

Recently, however, as a method to use limited energy resources more efficiently and reduce energy consumption, a method is being taken in which energy prices are differentiated by dividing them in time or season.

As a technology to promote an efficient usage of electric energy, attention is being focused on a Smart Grid or a Smart Meter.

The smart grid is a next generation power network that can optimize energy efficiency and create a new added value by grafting information technology (IT) onto a power network so that power suppliers and consumers can exchange information in a real time manner.

Viewing the smart grid from the standpoint of an energy consumer, the energy consumer can use energy at the most reasonable time zone while energy price is changing.

Meanwhile, a large capacity battery in which electric energy can be charged and discharged is being distributed and charging the battery with a low price is an object of attention under the price change system where electricity price changes depending on time of day.

Further, when the electricity price changes depending on time of day due to the difference between demand and supply in a smart grid society, the electric energy can have a feature of a product that can be purchased and sold by everyone, not limited to a feature that a power company unilaterally supplies users.

Since the electric energy can be stored in a battery even though it is an intangible product, it can be managed by a user. In this regard, a battery can serve to store electric energy as a product as well as to simply drive a load that is driven using the electric energy, like an electric vehicle.

Therefore, in the smart grid society where the electricity price changes depending on time of day, there occurs a need to develop various methods in which users can treat and use the electric energy more actively.

### SUMMARY OF THE INVENTION

The present disclosure provides charging/discharging apparatus and method in which a user can use electric energy actively while suitably controlling battery charging and discharging under a price change system in which the electricity price changes depending on time of day.

According to an aspect of the present disclosure, there is provided a charging/discharging apparatus, including a receiving unit for receiving price information of electricity depending on time of day from a central server, a first input unit for inputting electricity price to charge a battery; a second input unit for inputting electricity price to discharge the battery; and a charging/discharging unit for charging the battery when the price information of electricity received is equal to or less than the electricity price inputted through the first input unit and discharging the battery when the price information of electricity received is equal to or higher than the electricity price inputted through the second input unit.

According to an embodiment of the present disclosure, the charging/discharging apparatus may include a receiving unit for receiving price information of electricity depending on time of day from a central server, a first input unit for inputting electricity price to charge a battery; a second input unit for inputting electricity price to discharge the battery; a comparing unit for comparing the price information of electricity received with the electricity prices inputted through the first and second input units; and a charging/discharging unit for charging the battery when the price information of electricity received is equal to or less than the electricity price inputted through the first input unit, and discharging the battery when the price information of electricity received is equal to or higher than the electricity price inputted through the second input unit, on the basis of a comparison result at the comparing unit.

According to an embodiment of the present disclosure, the battery may be a battery for an electric vehicle.

According to an embodiment of the present disclosure, the charging/discharging unit may control a power supply or an outlet connected to the battery.

According to an embodiment of the present disclosure, the charging/discharging apparatus may further include a metering unit to identify at least one of the amount of electricity and an electric rate related with the charging/discharging of the battery.

According to an embodiment of the present disclosure, the metering unit may include a smart meter.

According to an embodiment of the present disclosure, the metering unit may predict an electric rate related with the charging/discharging of the battery using battery capacity information.

According to an embodiment of the present disclosure, the metering unit may predict an electric rate to be charged from a power company on the basis of the price information of electricity inputted through the first and second input units.

According to an embodiment of the present disclosure, the electric fare information identified by the metering unit may be transmitted to at least one of the central server, a user mobile terminal and an IHD (In Home Display).

According to an embodiment of the present disclosure, the metering unit may monitor whether the electric rate cost to charge the battery during a specified period exceeds an upper limit value set in advance.

According to an embodiment of the present disclosure, a warning message may be transmitted to at least one of the user mobile terminal and IHD according to a result of the monitoring.

According to an embodiment of the present disclosure, the charging/discharging unit may not discharge the battery but charge the battery according to a user setting.

According to an embodiment of the present disclosure, the charging/discharging unit may receive battery characteristic information from a user, and charge or discharge the battery according to the battery characteristic information.

According to an embodiment of the present disclosure, the charging/discharging unit may receive charging amount reference information from a user, and charge the battery according to the charging amount reference information.

According to an embodiment of the present disclosure, the charging/discharging unit may receive discharging amount reference information from a user, and discharge the battery according to the discharging amount reference information.

According to an embodiment of the present disclosure, the charging/discharging unit may determine schedules to charge and discharge the battery on the basis of time of day or the electricity price, and charge or discharge the battery according to the determined schedule.

According to an embodiment of the present disclosure, the charging/discharging unit may determine the schedule in order to make the user have the most profit to the maximum.

According to an embodiment of the present disclosure, the number of the batteries may be two or more, and the charging/discharging unit may separately determine the schedule for each battery or determine the schedule in battery group.

According to another aspect of the present disclosure, there is provided a charging/discharging method, including receiving price information of electricity depending on time of day from a central server at a receiving step; inputting electricity price to charge a battery at a first input step; inputting electricity price to discharge the battery at a second input step; and charging the battery when the price information of electricity received is equal to or less than the electricity price inputted at the first input step and discharging the battery when the price information of electricity received is equal to or higher than the electricity price inputted at the second input step, at a charging/discharging step.

According to an embodiment of the present disclosure, the charging/discharging method may include receiving price information of electricity depending on time of day from a central server at a receiving step; inputting electricity price to charge a battery at a first input step; inputting electricity price to discharge the battery at a second input step; and charging the battery when the price information of electricity received is equal to or less than the electricity price inputted at the first input step and discharging the battery when the price information of electricity received is equal to or higher than the electricity price inputted at the second input step; comparing the price information of electricity received with the prices of electricity inputted at the first and second input steps at a comparing step; and charging the battery when the price information of electricity received is equal to or less than the electricity price inputted at the first input step, and discharging the battery when the price information of electricity received is equal to or higher than the electricity price inputted at the second input step, at the charging/discharging step, on the basis of a comparison result at the comparing step.

According to an embodiment of the present disclosure, a power supply or an outlet that is connected to the battery may be controlled in order to charge and discharge the battery at the charging/discharging step.

According to an embodiment of the present disclosure, the charging/discharging method may further include metering at least one of the amount of electricity and an electric rate that are related with the charging/discharging of the battery at a metering step.

According to an embodiment of the present disclosure, the metering step may be performed by a smart meter.

According to an embodiment of the present disclosure, the electric fare related with the battery charging/discharging may be predicted using battery capacity information at the metering step.

According to an embodiment of the present disclosure, an electric fare to be received from a power company may be predicted on the basis of price information of electricity that is input through the first and second input steps at the metering step.

According to an embodiment of the present disclosure, the fare information of electricity identified at the metering step may be transmitted to a central server, a user mobile terminal and an IHD (In Home Display).

According to an embodiment of the present disclosure, it may be monitored whether an electric fare cost to charge the battery during a specific period exceeds an upper limit value set in advance at the metering step.

According to an embodiment of the present disclosure, a warning message may be transmitted to the user mobile terminal and the IHD according to a result of the monitoring.

According to an embodiment of the present disclosure, the battery discharging may not be performed and battery charging only may be performed according to a user's setting at the charging/discharging step.

According to an embodiment of the present disclosure, battery characteristic information may be input from the user and the battery may be charged or discharged according to the battery characteristic information at the charging/discharging step.

According to an embodiment of the present disclosure, charging amount reference information may be input from the user and the battery may be charged according to the charging amount reference information at the charging/discharging step.

According to an embodiment of the present disclosure, discharging amount reference information may be input from the user and the battery may be discharged according to the discharging amount reference information at the charging/discharging step.

According to an embodiment of the present disclosure, schedules to charge and discharge the battery may be determined on the basis of time of day or electricity price and the battery may be charged or discharged according to the determined schedule at the charging/discharging step.

According to an embodiment of the present disclosure, the schedule may be determined in order that the user makes the most profit economically at the charging/discharging step.

According to an embodiment of the present disclosure, the number of the batteries may be two or more, and the schedule may be separately determined for each battery or may be determined in battery group at the charging/discharging step.

According to the present disclosure, a user can plan to charge and discharge a battery by setting his or her available electricity price under a price change system in which the electricity price changes depending on time of day.

The user charges the battery when the electricity price is low and collects when the electricity price is high depending on the plan, so that the electricity can be consumed at an energy consuming place such as home, office and company or sold to the power company again.

Therefore, an Uninterruptible Power Supply (UPS) that stores electric energy and then provides power in case of emergency such as a power failure, a battery for an electric vehicle, or a battery that is arbitrarily included by a user may be served as a small-sized power generator.

Since charge and discharge are performed according to the electricity price that changes depending on time of day and charging and discharging reference prices that are set by a user, it is possible for a common user who does not have the knowledge of electricity to make a plan to use electric energy with ease.

The user can save the electricity price by controlling charging and discharging electric energy more actively and also make economic benefits by selling the electric energy to the power company as a product.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description, serve to explain the principle of the disclosure. In the drawings:

FIG. 1 shows an embodiment of a charging/discharging system according to the present disclosure;

FIG. 2 shows examples illustrating a price structure of electricity;

FIG. 3 illustrates a flow chart indicating a basic operation of a charging/discharging unit;

FIG. 4 shows an example schematically illustrating an operational state of a battery depending on the electricity price;

FIGS. 5 and 6 show embodiments of a charging/discharging apparatus according to the present disclosure;

FIG. 7 is a detailed embodiment of a charging/discharging unit;

FIGS. 8 and 9 show detailed embodiments of a charging/discharging unit;

FIG. 10 shows an example describing how to determine a charging/discharging schedule to make the maximum benefit for a user;

FIG. 11 shows an example describing how to determine a charging/discharging schedule based on time of day;

FIGS. 12 and 13 show examples of a charging/discharging unit when a plurality of batteries are used; and

FIGS. 14 and 15 show embodiments of a charging/discharging method according to a present disclosure.

### DETAILED DESCRIPTION OF THE PREFERRED EMBODIMENTS

Hereinafter, a preferred embodiment of the present disclosure will be described with reference to the accompanying drawings.

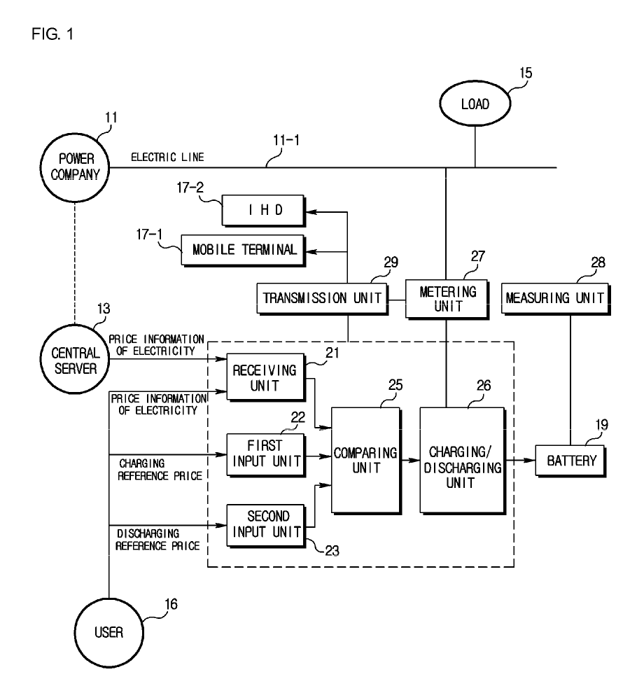

FIG. 1 shows an embodiment of a charging/discharging system according to the present disclosure, wherein a user 16 can charge or discharge a battery 19 according to the electricity price that changes depending on time of day.

The term ‘discharging’ as used herein means retrieving electric energy stored in the battery 19 again.

The electric energy discharged may be used as energy to drive all kinds of loads 15 included in energy consumption places such as TV set, audio set, refrigerator and heater or sold to a power company 11 again.

The power company 11 supplies electric energy, and the electric energy supplied from the power company 11 is distributed on electric lines 11-1, passes through a substation or the like, is converted into an appropriate voltage level and is applied to an energy consumption place.

The battery 19 may be a dedicated battery such as a battery for an UPS or a battery for an electric vehicle, each one used for its own purpose, or a battery that is held in order that a user charges it when the electricity price is low and discharges it when the price is high, so as to operate the load 15 in the energy consumption place or to sell the charged electricity again.

The electricity price changes depending on time of day under a price change system, and price information of electricity depending on time of day is transmitted by a central server 13.

The central server 13 is a server that is operated by a power company or a business that provides each user with the price information of electricity through a variety of communication network such as a wireless mesh, a power line network, and an Internet network.

The charging/discharging system may be variously constructed, including at least a receiving unit 21, a first input unit 22, a second input unit 23 and a charging/discharging unit 26.

Further, the charging/discharging system may further include a comparing unit 25, a gauge unit 27, a metering unit 28, and a transmission unit 29.

The first input unit 22 enables a user 16 to input electricity price at which a battery 19 is charged. That is, the user 16 inputs electricity price at which the battery 19 is to be charged through the first input unit 22.

Hereinafter, the electricity price that is input through the first input unit 22 is referred to a ‘charging reference price’.

The second input unit 23 enables the user 16 to input the electricity price at which the battery 19 is discharged. That is, the user 16 inputs a price of the electricity at which the battery 19 is to be discharged and used elsewhere.

Hereinafter, the electricity price that is input through the second input unit 23 is referred to ‘discharging reference price’.

The first and second input units 22 and 23 are components interfacing to the user, which can have various structures and forms.

For example, they can be constructed such that the user inputs the charging and discharging reference prices through a key pad or a touch screen, or remotely inputs them through other devices such as a user mobile terminal 17-1 or an IHD (In Home Display) 17-2.

Information on the charging and discharging reference prices that the user 16 has input through the first and second input units 22 and 23 can be transferred to a comparing unit 25 or a charging/discharging unit 26 by way of various paths. Further, the information can be transferred immediately after the user 16 inputs the information or accessed when the information is needed.

The comparing unit 25 compares price information of electricity received through the receiving unit 21 with the charging and discharging reference prices.

The charging/discharging unit 26 charges or discharges the battery 19 using a comparing result of the comparing unit 25.

That is, the charging/discharging unit 26 converts an alternating AC current applied into the energy consumption place through an electric line 11-1 into a direct DC current and then charges the battery 18, or converts the direct DC current of the battery 19 into an alternating AC current and then collects it.

The electricity price depending on time of day may have various structures under a price charging system.

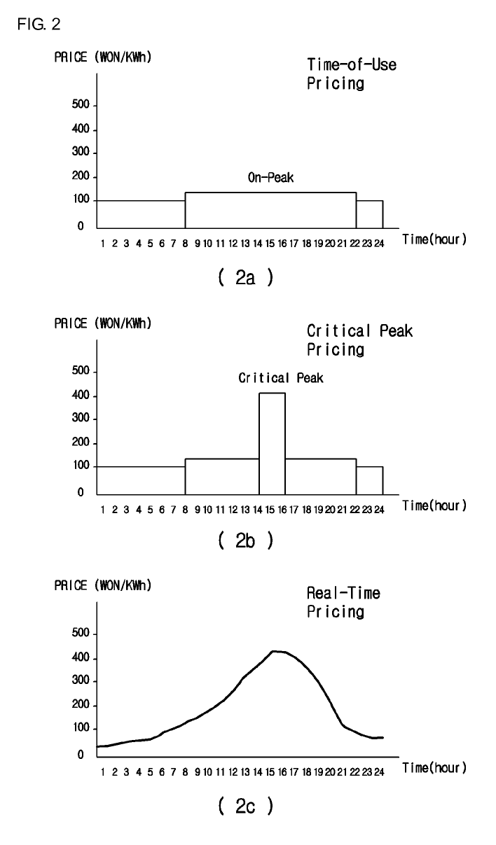

FIG. 2 shows examples illustrating a price structure of electricity that changes depending on time of day, FIG. 2a illustrating a Time of Use Pricing TOU that is normally used in shops, factories and large buildings, FIG. 2b illustrating a Critical Peak Pricing CPP in which prices of electricity are different depending on time of day and the electricity price at the peak section is very high, and FIG. 2c illustrating a Real-Time Pricing in which the electricity price changes in a real time.

Price information of electricity depending on time of day may be input through various paths, and the receiving unit 21 serves to receive the price information of electricity.

The receiving unit 21 can receive the price information of electricity depending on time of day that the central server 13 transmits through a communication network.

As another example, the receiving unit 21 can be constructed such that the user 16 can directly input the price information of electricity into it.

That is, when a power company 11 informs the user 16 of the price information of electricity through facsimile, text message and telephone, or announces the price information of electricity depending on time of day through an Internet web site or the like, the user 16 can identify the price information of electricity depending on time of day through them.

Then, the user 16 can directly input the electricity price depending on time of day.

The receiving unit 21 can provide a User interface UI such that the user 16 can input the price information of electricity depending on time of day, or receive the price information of electricity from another apparatus, for example, the user mobile terminal 17-1 or the IHD 17-2, to which the user inputs the price information of electricity.

An interface interposed between the receiving unit 21 and the comparing unit 25 or the charging/discharging unit 26 to exchange the price information of electricity therebetween, can be variously constructed according to a structure of the charging/discharging system.

For example, the receiving unit 21 may not be integrated with the comparing unit 25 or the charging/discharging unit 26, and in this case can exchange the price informant of electricity depending on time of day through various wired or wireless communication methods.

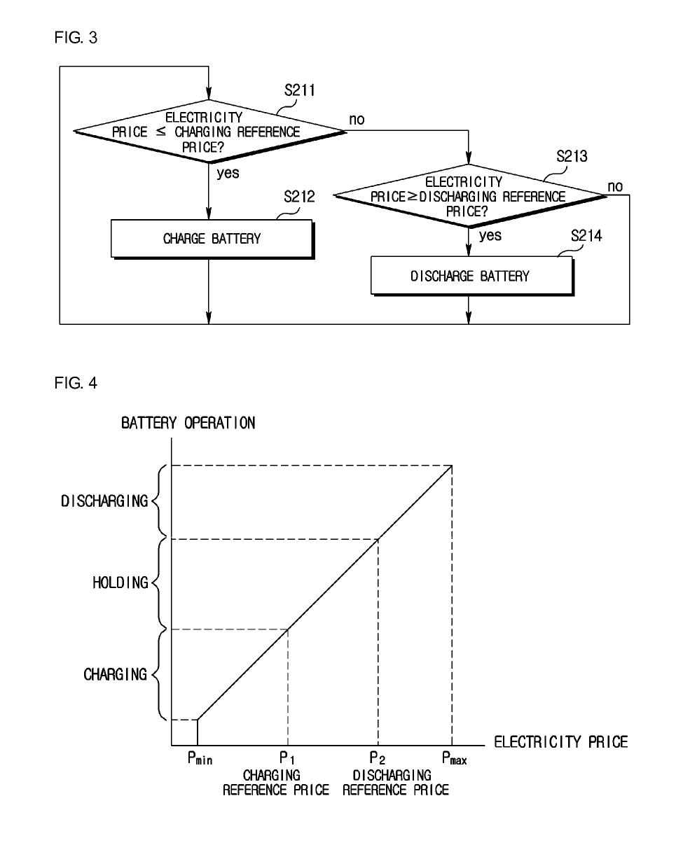

Describing a basic operation of the charging/discharging unit 26 with reference to FIG. 3, the charging/discharging unit 26 operates to charge the battery 19 when the electricity price is equal to or less than the charging reference price (S211, S212), and operates to discharge the battery 19 when the electricity price is equal to or greater than the discharging reference price (S213, S214).

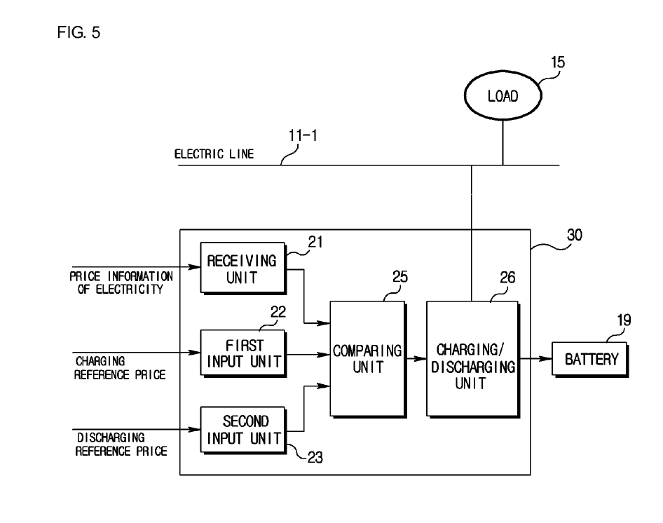

FIG. 4 shows an example schematically illustrating an operation of the charging/discharging unit 26, in which a charging reference price input by a user is assumed to be P1, a discharging reference price input by the user is assumed to be P2, the minimum electricity price supplied from the power company 11 is assumed to be Pmin, and the maximum electricity price supplied from the power company 11 is assumed to be Pmax.

Then, the charging/discharging unit 26 charges the battery 18 when the electricity price is between the Pmin and the P1, and discharges the battery 19 when the electricity price supplied from the power company 11 is between the P2 and the Pmax.

However, when the electricity price supplied from the power company 11 exceeds the P1 and less than the P2, it does not perform the charging/discharging operation.

The charging/discharging system may further include a metering unit 27, a measuring unit 28 and a transmission unit 29 in order to control the charging/discharging operation of the battery 19 in more detail or improve its function.

The metering unit 27 serves as a meter to identify the amount of electricity consumed when charging the battery 19 or the electricity price, or the amount of electricity collected when discharging the battery 19 or the electricity price.

Such a metering unit 27 may be constructed using a smart meter, and installed in an arbitrary place where electric energy transferred to the battery 19 or collected from the battery 19 can be detected.

The measuring unit 28 serves to detect capacity information of the battery 19, and more particularly remaining capacity information of the battery 19.

The metering unit 27 may predict the electricity price needed when charging the battery or the electricity price that will occur when discharging the battery, on the basis of the detected remaining capacity information of the battery and the price information of electricity received through the receiving unit 21.

For example, when it is assumed that a current remaining capacity ratio of the battery 19 is 60% and the amount of electricity when the battery 19 is completely charged is Qmax, the electricity price needed when charging the battery 19 can be predicted by multiplying the amount of electricity, ‘Qmax×0.4’ by a unit electricity price, and the electricity price needed when discharging the battery 19 can be predicted by multiplying the amount of electricity, ‘Qmax×0.6’ by the unit electricity price.

Further, the metering unit 27 may predict the electricity price needed when charging the battery 19 or the electricity price that will occur when discharging the battery 19, or predict the electricity price that will be paid by the power company 11 when discharging the battery, on the basis of the charging reference price and discharging reference price.

In the example, the electricity price needed when charging the battery will be predicted by multiplying the amount of electricity, ‘Qmax×0.4’ by the charging reference price, and the electricity price that will occur when discharging the battery can be predicted by multiplying the amount of electricity, ‘Qmax×0.6’ by the discharging reference price.

While the electricity price that will be paid by the power company 11 when discharging the battery may be the same as the electricity price that will occur when discharging the battery, it may be constructed to apply a resale price of electric energy that is specifically set between the user and the power company 11 or to predict the amount of money that the user can actually receive after deducting taxes or the like.

As such, the metering unit 27 can identify or predict a variety of information related with the charging/discharging of the battery 19.

The transmission unit 29 serves to transmit kinds of information related with operations of the charging/discharging system to other apparatuses.

At this time, various wired or wireless communication methods may be used and information may be transmitted through a wide area network such as a mobile communication network.

An example of the information to be transmitted by the transmission unit 29 is information that is identified or predicted by the metering unit 27. Detailed examples can include the electricity price related with charging/discharging of the battery 19, the predicted prices of electricity when charging and discharging the battery, and the electricity price that will be paid by the power company.

The transmission unit 29 can transmit such information to the central server 13, the user mobile terminal 17-1, and the IHD (In Home Display) 17-2.

Further, the metering unit 27 may be constructed to monitor whether the amount of electricity used to charge the battery 19 during a specified period or the electricity price exceeds the upper limit value that has been set in advance.

In this case, when the amount of electricity with which the battery 19 has been charged or the electricity price exceeds the upper limit value set in advance as a result of monitoring the metering unit 27, the transmission unit 29 can transmit a warning message to the user mobile terminal 17-1 or the IHD (In Home Display) 17-2.

The upper limit value can be set by the user 16. When a discharging has been performed, it can be determined whether the upper limit value has been exceeded only with the electricity price produced by subtracting the electricity price occurred when discharging the battery from the electricity price occurred when charging the battery.

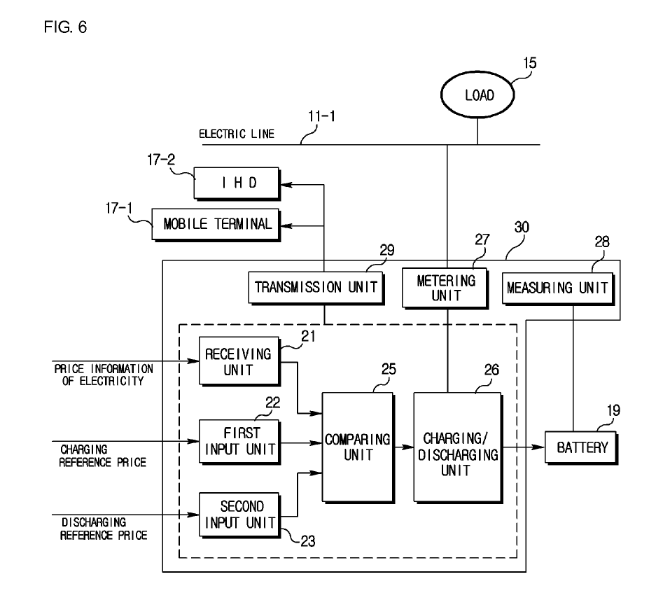

FIG. 5 shows an embodiment of a charging/discharging apparatus 30 according to the present disclosure, wherein the charging/discharging apparatus 30 is constructed of at least a receiving unit 21, a first input unit 22, a second input unit 23 and a charging/discharging unit 26, and may further include a comparing unit 25 to compare price information of electricity that is received through the receiving unit 21 with the electricity price that has been input through the first and second input units 22 and 23.

FIG. 6 shows another embodiment illustrating a charging/discharging apparatus 30 according to the present disclosure, which may further include a metering unit 27, a measuring unit 28 and a transmission unit 29 in order to the charging/discharging operation of the battery 19 or enhance its function.

Since the functions of the receiving unit 21, the first input unit 22, the second input unit 23, the comparing unit 25, the charging/discharging unit 26, the metering unit 27, the measuring unit 28 and the transmission unit 29 of the charging/discharging apparatus 30 according to the present disclosure are the same as those of the charging/discharging system described above, overlapping detailed description will be omitted and the gist of it will be described.

The first input unit 22 is used to input a charging reference price at which the user wishes to charge the battery 19, and the second input unit 23 is used to input a discharging reference price at which the user wishes to discharge the battery 19.

The first and second input units 22 and 23 are components that interface with the user, which can be variously constructed.

The charging/discharging unit 26 charges or discharges the battery 19 according to the electricity price depending on the charging reference price, the discharging reference price and time of day. That is, the charging/discharging unit 26 charges the battery 19 when the electricity price is equal to or less than the charging reference price, and discharges the battery 19 when the electricity price is equal to or higher than the discharging reference price.

The price structure of electricity under the price changing system can be variously constructed as described in FIG. 2.

Price information of electricity depending on time of day may be input through various paths, and the receiving unit 21 serves to receive the price information of electricity.

The receiving unit 21 can be constructed such that it receives the price information of electricity depending on time of day that the central server 13 transmits through a communication network, or the user can directly input the price information of electricity.

In the case of the latter, the receiving unit 21 can provide a user interface in order that the user can input the price information of electricity depending on time of day, or receive the price information of electricity from another apparatus such as the user mobile terminal 17-1 or the IHD 17-2 with which the user input the price information of electricity depending on time of day.

The metering unit 27 serves as a meter to identify the amount of electricity consumed when charging the battery 19 or the electricity price, or the amount of electricity collected when discharging the battery 19 or the electricity price.

Such a metering unit 27 may be constructed using a smart meter, and installed in an arbitrary place where electric energy transferred to the battery 19 or collected from the battery 19 can be detected.

The measuring unit 28 serves to detect capacity information of the battery 19, and more particularly remaining capacity information of the battery 19.

The metering unit 27 may predict the electricity price needed when charging the battery or the electricity price that will occur when discharging the battery, on the basis of the detected remaining capacity information of the battery and the price information of electricity received through the receiving unit 21.

Further, the metering unit 27 may predict the electricity price needed when charging the battery 19 or the electricity price that will occur when discharging the battery 19, or predict the electricity price that will be paid by the power company 11 when discharging the battery, on the basis of the charging reference price and discharging reference price.

The transmission unit 29 serves to transmit kinds of information related with the operation of the charging/discharging apparatus 30 to other apparatuses. At this time, the transmission unit can use various wired or wireless communication methods, and may transmit information through a wide area network such as a mobile communication network.

An example of the information to be transmitted by the transmission unit 29 is information that is identified or predicted by the metering unit 27. Detailed examples can include the electricity price related with charging/discharging of the battery, the predicted prices of electricity when charging and discharging the battery, and the electricity price that will be paid by the power company.

The transmission unit can transmit such information to the central server 13, the user mobile terminal 17-1, and the IHD (In Home Display) 17-2.

Further, the metering unit 27 may be constructed to monitor whether the amount of electricity used to charge the battery 19 during a specified period or the electricity price exceeds the upper limit value that has been set in advance.

In this case, when the amount of electricity with which the battery 19 has been charged or the electricity price exceeds the upper limit value set in advance as a result of monitoring the metering unit 27, the transmission unit 29 can transmit a warning message to the user mobile terminal 17-1 or the IHD (In Home Display) 17-2.

The upper limit value can be set by the user. When a discharging has been performed, it can be determined whether the upper limit value has been exceeded only with the electricity price produced by subtracting the electricity price occurred when discharging the battery from the electricity price occurred when charging the battery.

From now, various embodiments will be described, in which the charging/discharging unit 26 of the charging/discharging system and the charging/discharging apparatus according to the present disclosure controls a charging/discharging of the battery.

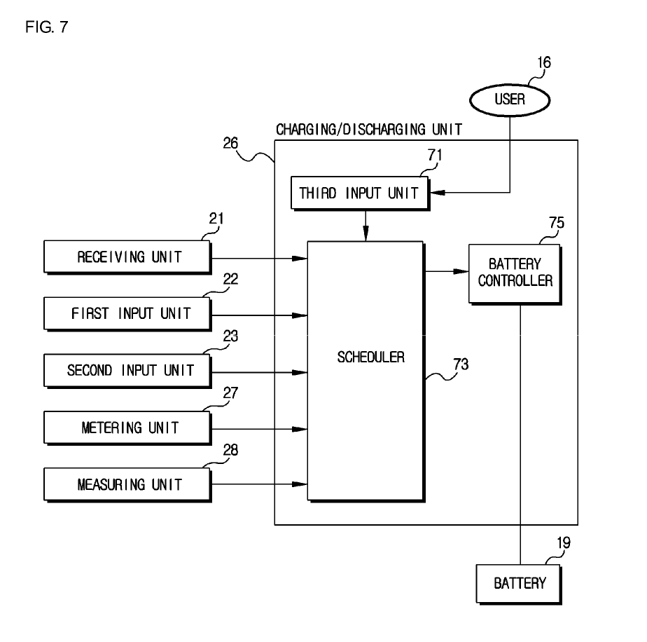

FIG. 7 is a detailed embodiment of the charging/discharging unit 26, which can be constructed of a third input unit 71, a scheduler 73 and a battery controller 75.

The third input unit 71 enables the user to input information needed to control charging/discharging of the battery 19 (hereinafter, referred to information on the charging/discharging condition), other than the charging reference price and the discharging reference price.

The information on charging/discharging condition can be variously constructed according to the need.

For example, it can include charging/discharging mode information used to determine whether a discharging function of the battery should be non-activated, battery characteristic information such as time needed to charge or discharge the battery, information on the reference amount of charging, and information on the reference amount of discharging.

Here, the information on the reference amount of charging means information on what level the battery 19 should be charged to, which can include a target amount of charging in battery (for example: a remaining capacity ratio of battery), a target consuming amount of electricity regarding how much electricity will be used for charging, and a target charging fare regarding how much electricity will be used for charging.

The information on the reference amount of discharging means information on what level the battery 19 should be discharged to, which can include a target amount of charging in battery (for example: a remaining capacity ratio of battery) regarding until when the battery is discharged, that is, up to how much capacity the battery holds as a remainder, a target discharging amount of electricity regarding how much electricity the battery discharges, and a target discharging fare regarding how much electricity will be used for discharging.

The third input unit 71 is a component used to interface with the user, which can be constructed to have various structures and forms.

For example, the third input unit may be constructed in that the user directly inputs the information through a key pad or a touch screen, or remotely inputs the information through the user mobile terminal 17-1 or the IHD (In Home Display) 17-2.

The scheduler 73 determines a schedule to charge or discharge the battery 19, using price information of electricity depending on time of day that is input through the receiving unit 21, charging reference price information that is input through the first input unit 22, information on a charging/discharging condition that is input through the third input unit 71, information that can be input through the metering unit 27, and information on a battery capacity that can be input through the measuring unit 28.

Further, the scheduler 73 makes the battery 19 in a charging state or a discharging state by controlling the battery controller 75 according to a determined schedule.

The battery controller 75 controls the battery 19 in a charging state by converting an alternating AC current applied into an energy consumption place through an electric line 11-1 into a direct DC current and supplying the battery with it according to a control of the scheduler 73, or controls the battery 19 in a discharging state by converting the direct DC current of the battery 19 into the alternating AC current and transmitting it to the electric line 11-1.

At this time, the battery controller 75 can be constructed to control charging and discharging of the battery by controlling a contact or an outlet with which the battery 19 and the electric line 11-1 are connected to be connected or opened.

The scheduler 73 may not perform a discharging function if a charging/discharging mode input through the third input unit 71 makes the discharging function non-active.

For example, when the battery 19 is a battery for an electric vehicle, the user may not want the battery 19 to be discharged if the user uses the electric vehicle for commuting. As such, if the user is interested only in charging the battery 19 when the electricity price is low and not in discharging the battery, the battery discharging function may be non-activated for the sake of user's convenience.

The scheduler 73 can determine a charging schedule of the battery in consideration of charging amount reference information as well as a charging reference price.

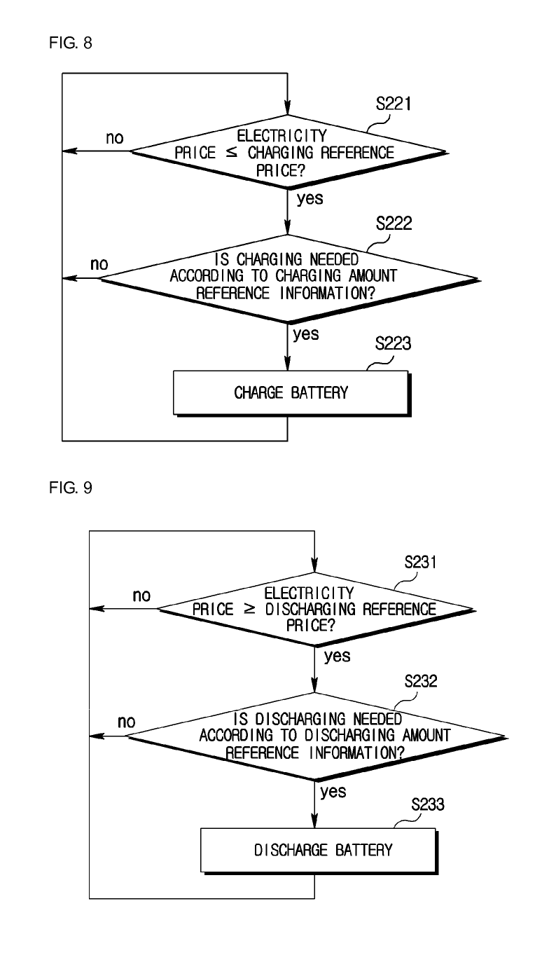

Referring to FIG. 8, the scheduler 73 controls the battery controller 75 to charge the battery 19 only when the electricity price is equal to or less than the charging reference price (S221) and it is needed to charge the battery according to the charging amount reference information (S222, S223).

That is, even though the electricity price is equal to or less than the charging reference price, the battery 19 is charged when a current charging state of the battery 19 does not reach the target battery charging amount, the amount of electricity used to charge the battery does not reach the target electricity usage amount, or the electricity price used to charge the battery does not reach the target charging fare.

It is of course that such various conditions can be combined using ‘AND’ or ‘OR″ combinations according to the need.

The scheduler 73 can determine a discharging schedule of the battery in consideration of discharging amount reference information as well as a discharging reference price.

Referring to FIG. 9, the scheduler 73 controls the battery controller 75 to discharge the battery 19 only when the electricity price is equal to or higher than the discharging reference price (S231) and it is needed to discharge the battery according to the discharging amount reference information (S232, S233).

That is, even though the electricity price is equal to or higher than the discharging reference price, the battery 19 is discharged when a current discharging state of the battery 19 is equal to or higher than the target battery discharging amount, the amount of electricity discharged did not reach the target electricity discharging amount, or the electricity price obtained by discharging the battery did not reach the target discharging fare.

It is of course that such various conditions can be combined using ‘AND’ or ‘OR″ combinations according to the need.

The scheduler 73 can determine a charging/discharging schedule to give the user economic benefits to the maximum.

When the electricity price changes depending on time of day as described with reference to FIG. 4, a price zone in which the battery 19 can be charged ranges from the minimum electricity price, Pmin, to the charging reference price, p1, and a price zone in which the battery 19 can be discharged ranges from the discharging reference price, P2, to the maximum electricity price, Pmax.

The user can make a profit when the charging is performed at as low electricity price as possible, and when the discharging is performed at as high electricity price as possible. Therefore, the scheduler 73 determines the schedule such that the charging is performed at as low electricity price as possible and discharged at as high electricity price as possible.

In relation with this, the scheduler 73 can determine the charging/discharging schedule using battery characteristic information.

Assuming that the battery characteristic information is a standard time taken to charge the battery 19 and a standard time taken to discharge the battery 19, the scheduler 73 can determine a battery charging schedule using battery characteristic information, battery remaining capacity information and battery charging amount reference information.

Further, the scheduler 73 can determine a battery discharging schedule using battery characteristic information, battery remaining capacity information, and battery discharging amount reference information.

That is, the scheduler 73 identifies charging and discharging timing at which the user can make the most profit using the price information of electricity depending on time of day and accordingly determines the charging schedule and the discharging schedule.

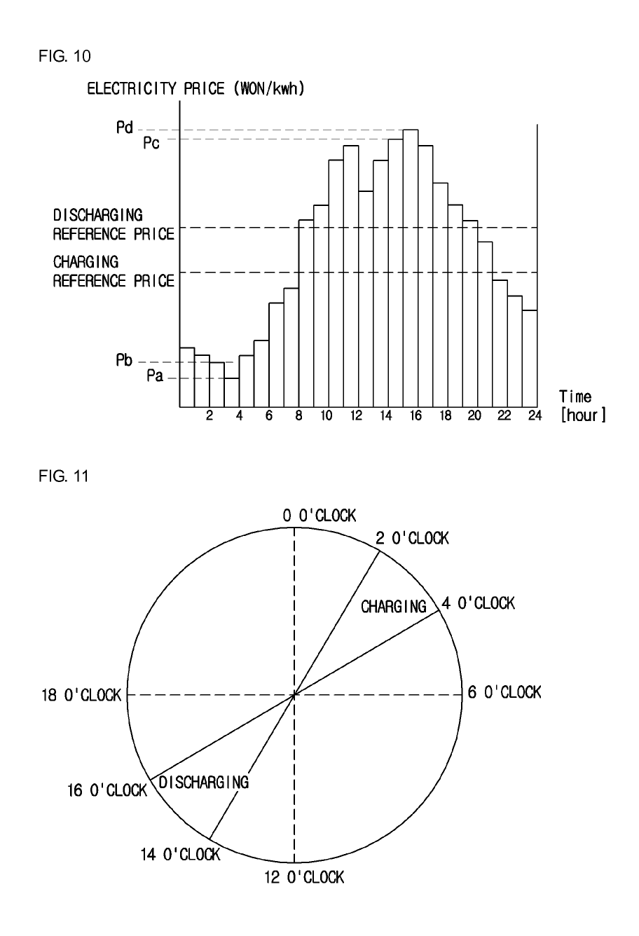

FIG. 10 shows a detailed example of electricity price changing depending on time of day. A method to determine the charging and discharging schedule so as to make the user have the most economic profit will be described with reference to the drawing.

Assume that a standard time to completely charge the battery is 5 hours, a current remaining capacity of the battery is 60% and a target battery charging amount that the user set as a ratio of the battery remaining capacity is 100%.

Then, the scheduler 73 can expect that it takes 2 hours to charge the battery since it is needed to more charge 40% of the battery capacity.

Now, the scheduler 73 sorts 2 hours staring from the lowest price section of electricity with reference to the price information of electricity depending on time of day, and the lowest price section of electricity in FIG. 10 is from 02 o'clock to 04 o'clock. Accordingly, the scheduler 73 determines a charging schedule and controls the battery controller 75 such that the charging is performed from 02 o'clock to 04 o'clock, so that the charging is performed at the relevant time.

Further, assume that a standard time to completely charge the battery is 5 hours, a current remaining capacity of the battery is 90% and a target battery discharging amount that the user set as a ratio of the battery remaining capacity is 50%.

Then, the scheduler 73 can expect that it takes 2 hours to discharge the battery since it is possible to discharge 40% of the battery capacity.

Now, the scheduler 73 sorts 2 hours staring from the highest price section of electricity with reference to the price information of electricity depending on time of day, and the highest price section of electricity in FIG. 10 is from 14 o'clock to 16 o'clock.

Accordingly, the scheduler 73 determines a discharging schedule and controls the battery controller 75 such that a discharging is performed from 14 o'clock to 16 o'clock, so that the discharging is performed at the relevant time.

The scheduler 73 can determine the charging or discharging schedule on the basis of time or electricity price.

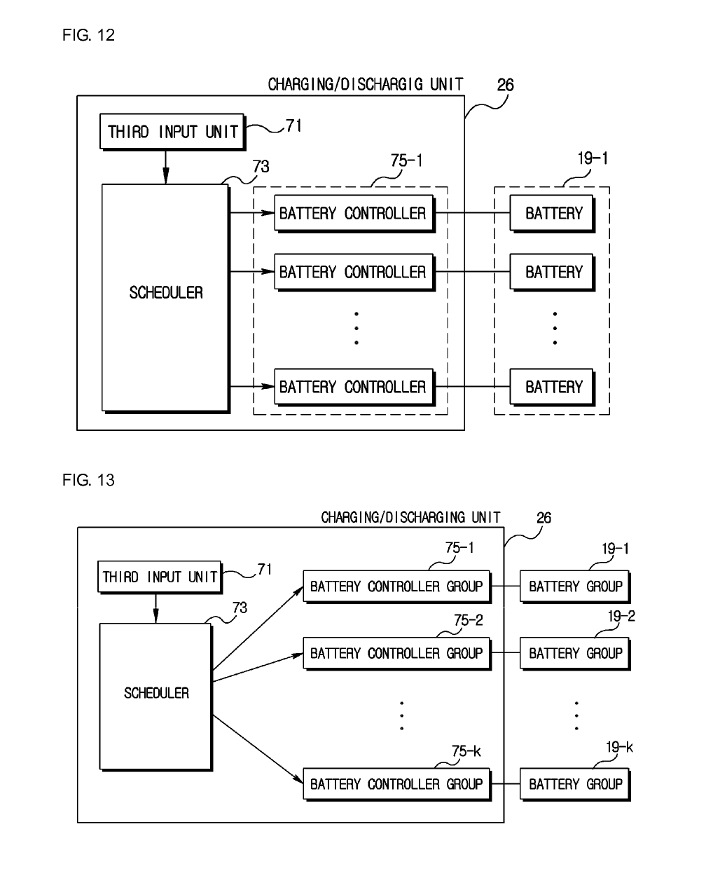

That is, the scheduler 73 can determine the charging schedule as from 02 o'clock to 04 o'clock as described in the above example, and the discharging schedule as from 14 o'clock to 16 o'clock. FIG. 11 schematically shows a charging/discharging schedule made on the basis of time.

In this case, the scheduler 73 identifies current time, and controls the battery controller 75 from 02 o'clock to 04 o'clock so as to perform the charging, and controls the battery controller 75 from 14 o'clock to 16 o'clock so as to perform the discharging.

Further, the scheduler 73 can determine the charging schedule on the basis of the electricity price, and the charging schedule is determined on the basis of the electricity price, Pa and Pb and the discharging schedule is determined on the basis of Pc and Pd in FIG. 10.

In this case, the scheduler 73 controls the battery controller 75 so that the charging is performed when the current electricity price is Pa or Pb, and controls the battery controller 75 so that the discharging is performed when the current electricity price is Pc or Pd.

The number of battery may be two or more.

In this case, the scheduler 73 can separately determine the charging schedule and discharging schedule with respect to each battery, or can determine them in each battery group by grouping the batteries.

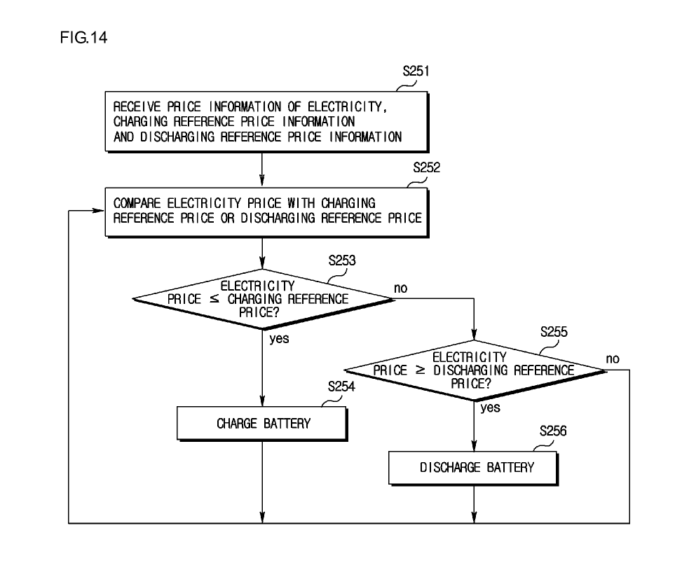

FIG. 12 shows an embodiment that includes battery controllers 75-1 correspondingly to a plurality of batteries 19-1, and separately determines charging and discharging schedules for each battery.

FIG. 13 shows an embodiment that determines charging and discharging schedules in each battery group by grouping a plurality of batteries, in which each battery group 19-1 to 19-k is controlled by each battery controller group 75-1 to 75-k that corresponds to the battery group, respectively.

When the plurality of batteries are managed by grouping them, an instable state of power flowing on an electric line due to the charging and discharging can be minimized so that the charging and discharging service according to the present disclosure can be stably performed. At this time, each battery group 19-1 to 19-k can be controlled so as to be charged and discharged in order.

Each battery of each battery group 19-1 to 19-k is in the charging and discharging state according to a schedule that is determined depending on each embodiment of the scheduler 73 described above.

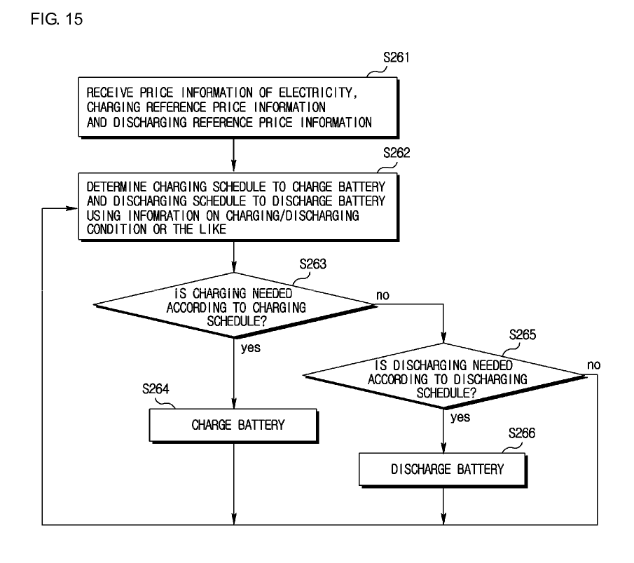

Now, an embodiment of charging and discharging method according to the present disclosure will be described with reference to FIGS. 14 and 15.

Referring to FIG. 14, an apparatus or a system that is used to charge and discharge a battery receives price information of electricity, charging reference price information and discharging reference price information that are provided from a power company (S251).

The user interface that enables the user to input the charging reference price information and the discharging reference price information at step S251 can be variously constructed.

For example, the interface can be constructed such that the user directly inputs the information through a key pad or a touch screen, or the user remotely input the information through other apparatuses such as a mobile terminal or an IHD (In Home Display).

The price information of electricity provided from the power company can have various structures under the price changing system as shown in FIG. 2.

Such price information of electricity can be constructed such that it is received from a central server through a communication network or the user directly input it. In the latter case, at step S251, a user interface can be provided in order that the user can input the price information of electricity depending on time of day, or the information can be received from another apparatus such as a user mobile terminal or an IHD, with which the user inputs the price information of electricity depending on time of day.

When the price information of electricity, the charging reference price information and the discharging reference price information that are provided from the power company are input at step S251, the price information of electricity is compared with the charging reference price or the discharging reference price (S252).

Further, when the electricity price provided from the power company is equal to or less than the charging reference price as a result of the comparison, the battery is charged (S253 and S254). Further, when the electricity price is equal to or higher than the discharging reference price, the battery is discharged (S255 and S256).

That is, according to the result of the comparison at step S252, an alternating AC current applied into an energy consumption place through an electric line is converted into a direct DC current and the battery is charged, or a direct DC current of the battery is converted into an alternating AC current and collected.

The charging/discharging method according to the present disclosure may further include a metering step in order to control the charging/discharging operation of the battery in more detail or enhance its function.

The metering step can be constructed to identify the amount of electricity consumed to charge the battery or the electricity price and the amount of electricity collected to discharge the battery or the electricity price.

Such metering step can be performed by a smart meter, and the smart meter can be transferred to the battery or installed at an arbitrary place where electric energy collected from the battery can be detected.

At the metering step, it may be possible to predict the electricity price needed to charge the battery or the electricity price to be occurred when discharging the battery on the basis of remaining capacity information of the battery and the price information of electricity.

For example, when it is assumed that a current remaining capacity ratio of the battery is 60% and the amount of electricity when the battery is completely charged is Qmax, the electricity price needed when charging the battery can be predicted by multiplying the amount of electricity, ‘Qmax×0.4’ by a unit electricity price, and the electricity price needed when discharging the battery can be predicted by multiplying the amount of electricity, ‘Qmax×0.6’ by the unit electricity price.

At this time, at the metering step, it may be possible to predict the electricity price needed when charging the battery or the electricity price to be occurred when discharging the battery, or predict the electricity price that will be paid by the power company when discharging the battery, on the basis of the charging reference price and discharging reference price.

In the example, the electricity price needed when charging the battery can be predicted by multiplying the amount of electricity, ‘Qmax×0.4’ by the charging reference price, and the electricity price to be occurred when discharging the battery can be predicted by multiplying the amount of electricity, ‘Qmax×0.6’ by the discharging reference price.

The fare of electricity that will be paid by the power company may be constructed to apply a resale price of electric energy that is specifically set between the user and the power company or to predict the amount of money that the user can actually receive after deducting taxes or the like.

Information on the fare of electricity related with charging or discharging of the battery identified or predicted at the metering step and the fare of electricity that will be paid from the power company can be transmitted to a central server, a user mobile terminal and an IHD (In Home Display) using various wired or wireless communication methods.

Further, the metering step may be constructed to monitor whether the amount of electricity used to charge the battery during a specified period or the fare of electricity exceeds an upper limit value that has been set in advance.

The upper limit value may be set by the user 16, and when the amount of electricity that has charged the battery exceeds the upper limit value that has been set in advance as a result of the monitoring, a warning message can be transmitted to the user mobile terminal or the IHD (In Home Display).

FIG. 15 shows another embodiment of the charging/discharging method according to the present disclosure, in which an apparatus or a system that enables the battery to be charged or discharged receives price information of electricity, charging reference price information, and discharging reference price information that are provided from a power company (S261).

Further, it receives information on a charging/discharging condition and determines schedules to charge and discharge the battery in order to control the charging/discharging of the battery in more detail (S262).

Here, the information on the charging/discharging condition means information that is input by the user in order to control the battery charging/discharging, other than the charging reference price and the discharging reference price, which can be variously constructed according to the need.

For example, it includes charging/discharging mode information that is used to determine whether the discharging function of the battery is non-activated, battery characteristic information such as time taken to change or discharge the battery, charging amount reference information and discharging amount reference information.

As described above, the charging amount information means information on the level to which the battery is charged, and the discharging amount reference information means information on the level to which the battery is discharged.

Further, when it is needed to charge the battery according to the charging schedule, a battery charging operation is performed (S263 and S264), and when it is needed to discharge the battery according to the discharging schedule, a battery discharging operation is performed (S265 and S266).

At this time, it can be constructed that battery charging or discharging is controlled by making a contact or outlet used to connect the battery and the electric line connected or open.

Various examples related with the charging/discharging schedule determined at step S262 will be described in detail.

When the charging/discharging mode that is input as information on the charging/discharging condition is to non-activate the discharging function, it is possible to determine a discharging schedule not to perform a discharging.

For example, in the case that the batter is a batter for an electric vehicle, when the user uses the electric vehicle for commuting, the user may not want to discharge the battery. As such, if the user is interested only in charging the battery 19 when the electricity price is low and not in discharging the battery, the battery may not be discharged for the sake of user's convenience.

The battery charging scheduler can be determined in consideration of the charging amount reference information as well as the charging reference price.

That is, as described with reference to FIG. 8, even though the electricity price is equal to or less than the charging reference price, when a current charging state of the battery did not reach a target battery charging amount, the amount of electricity used to charge the battery did not reach the target electricity usage amount or the fare of electricity used to charge the battery did not reach the target charging fare, the battery is charged.

The battery discharging schedule can be determined in consideration of the discharging reference information as well as the discharging reference price.

That is, as described with reference to FIG. 9, even though the electricity price is equal to or higher than the discharging reference price, when a current discharging state of the battery is equal to or higher than a target battery discharging amount, the amount of electricity to be discharged did not reach the target electricity discharging amount or the fare of electricity obtained by discharging the battery did not reach the target discharging fare, the battery is discharged.

It is of course that such various conditions can be combined by using ‘AND’ or ‘OR” combinations according to the need.

Further, the charging/discharging schedule can be determined to give the user economic benefits to the maximum.

When the electricity price changes depending on time of day as described with reference to FIG. 4, a price zone in which the battery can be charged ranges from the minimum electricity price, Pmin, to the charging reference price, P1, and a price zone in which the battery can be discharged ranges from the discharging reference price, P2, to the maximum electricity price, Pmax.

However, the user can make a profit when the charging is performed at as low electricity price as possible and when the discharging is performed at as high electricity price as possible.

At this time, the charging/discharging schedule can be determined using battery characteristic information.

Assuming that the battery characteristic information is information on a standard time taken to charge the battery and a standard time taken to discharge the battery, time taken to change the battery can be identified using battery characteristic information, battery remaining capacity information and battery charging amount reference information.

Further, time taken to discharge the battery can be identified using the battery characteristic information, the battery remaining capacity information and the battery discharging amount reference information.

Then, charging and discharging timing at which the user can make the most profit can be identified using the price information of electricity depending on time of day and accordingly the charging schedule and the discharging schedule can be determined. Detailed example related with it was described with reference to FIG. 10.

The charging schedule or discharging schedule can be determined on the basis of time of day or the electricity price.

That is, the charging schedule or discharging schedule can be determined on the basis of a specific time period or a specific price zone.

In the case of the former, at step S263, it is determined that charging is needed when current time belongs to a charging time zone, and at step S265, it is determined that discharging is needed when current time belongs to a discharging time zone.

In the case of the latter, at step S263, it is determined that charging is needed when a current electricity price belongs to a charging price, and at step S265, it is determined that discharging is needed when a current electricity price belongs to a discharging price.

Meanwhile, the number of the battery may be two or more.

In this case, at step S262, the charging schedule and discharging schedule can be separately determined for each battery or they can be determined for each battery group by grouping the batteries.

When the plurality of batteries are managed by grouping them, an unstable state of power flowing on an electric line due to the charging and discharging can be minimized so that the charging and discharging service according to the present disclosure can be stably performed. At this time, each battery group can be controlled so as to be charged and discharged in order.

Each battery of each battery group is in the charging and discharging state according to a schedule that is determined depending on each embodiment of the schedule determining method described above.

Hereinbefore, while the embodiments of the present disclosure are described, they are exemplary ones only and one of ordinary skill in the art may recognize that various alterations and modifications that fall within the scope of the present disclosure may be possible. Accordingly, the true technical protection scope of the present disclosure should be defined by the following claims.

What is claimed is:

1. A charging/discharging apparatus, comprising:
a receiving unit for receiving price information of electricity depending on time of day from a central server,
a first input unit for inputting electricity price to charge a battery;
a second input unit for inputting electricity price to discharge the battery; and
a charging/discharging unit for charging the battery when the price information of electricity received is equal to or less than the electricity price inputted through the first input unit and discharging the battery when the price information of electricity received is equal to or higher than the electricity price inputted through the second input unit.

2. The charging/discharging apparatus according to claim 1, further comprising a comparing unit for comparing the price information of electricity received with the prices of electricity inputted through the first and second input units,
wherein the charging/discharging unit charges the battery when the price information of electricity received is equal to or less than the electricity price inputted through the first input unit, and discharges the battery when the price information of electricity received is equal to or higher than the electricity price inputted through the second input unit, on the basis of a comparison result at the comparing unit.

3. The charging/discharging apparatus according to claim 1, wherein the battery is a battery for an electric vehicle.

4. The charging/discharging apparatus according to claim 1, wherein the charging/discharging unit controls a power supply or an outlet connected to the battery.

5. The charging/discharging apparatus according to claim 1, further comprising a metering unit to identify at least one of the amount of electricity and an electric rate that are related with the charging/discharging of the battery.

6. The charging/discharging apparatus according to claim 5, wherein the metering unit includes a smart meter.

7. The charging/discharging apparatus according to claim 5, wherein the metering unit predicts an electric rate related with the charging/discharging of the battery using battery capacity information.

8. The charging/discharging apparatus according to claim 5, wherein the metering unit predicts an electric rate to be charged from a power company on the basis of the price information of electricity inputted through the first and second input units.

9. The charging/discharging apparatus according to claim 5, further comprising a transmission unit to transmit the electric fare information identified by the metering unit to at least one of the central server, a user mobile terminal and an IHD (In Home Display).

10. The charging/discharging apparatus according to claim 5, wherein the metering unit monitors whether the electric rate cost to charge the battery during a specified period exceeds an upper limit value set in advance.

11. The charging/discharging apparatus according to claim 10, further comprising a transmission unit to transmit a warning message to at least one of the user mobile terminal and IHD according to a result of the monitoring.

12. The charging/discharging apparatus according to claim 1, wherein charging/discharging unit does not discharge the battery according to a user's setting.

13. The charging/discharging apparatus according to claim 1, wherein the charging/discharging unit receives battery characteristic information from a user, and charges or discharges the battery according to the battery characteristic information.

14. The charging/discharging apparatus according to claim 1, wherein the charging/discharging unit receives charging amount reference information from a user, and charges the battery according to the charging amount reference information.

15. The charging/discharging apparatus according to claim 1, wherein the charging/discharging unit receives discharging amount reference information from a user, and discharges the battery according to the discharging amount reference information.

16. The charging/discharging apparatus according to claim 1, wherein the charging/discharging unit determines schedules to charge and discharge the battery on the basis of time of day or the electricity price, and charges or discharges the battery according to the determined schedule.

17. A charging/discharging method, comprising:
receiving price information of electricity depending on time of day from a central server at a receiving step;
inputting electricity price to charge a battery at a first input step;
inputting electricity price to discharge the battery at a second input step; and
charging the battery when the price information of electricity received is equal to or less than the electricity price inputted at the first input step and discharging the battery when the price information of electricity received is equal to or higher than the electricity price inputted at the second input step, at a charging/discharging step.

18. The method according to claim 17, further comprising the step of comparing the price information of electricity received with the prices of electricity inputted at the first and second input steps,
wherein the battery is charged when the price information of electricity received is equal to or less than the electricity price inputted at the first input step, and discharged when the price information of electricity received is equal to or higher than the electricity price inputted at the second input step, at the charging/discharging step, on the basis of a comparison result at the comparing step.

19. The method according to claim 17, further comprising metering at least one of the amount of electricity and an electric rate that are related with the charging/discharging of the battery at a metering step.

20. The method according to claim 17, wherein schedules to charge and discharge the battery are determined on the basis of time of day or electricity price and the battery is charged or discharged according to the determined schedule at the charging/discharging step.
